(19) United States
(12) Patent Application Publication
(10) Pub. No.: US 2024/0237219 A1
(43) Pub. Date: Jul. 11, 2024

(54) STAGGERED FLIP PIN SMT CONNECTOR TO REDUCE CROSSTALK ON HIGH-SPEED CHANNELS

(71) Applicant: Intel Corporation, Santa Clara, CA (US)

(72) Inventors: Ifiok UMOH, San Jose, CA (US); Luz Karine SANDOVAL GRANADOS, Zapopan (MX); Alberto CARRILLO VAZQUEZ, Zapopan (MX); Quresh BOHRA, San Jose, CA (US); Diego Mauricio CORTES HERNANDEZ, Beaverton, OR (US)

(21) Appl. No.: 18/610,141

(22) Filed: Mar. 19, 2024

(51) Int. Cl. H05K 1/18; H01R 12/57

(52) U.S. Cl. CPC H05K 1/181; H01R 12/57; H05K 2201/10189

(57) ABSTRACT

Methods and apparatus for staggered flip pin SMT (surface mount technology) connectors to reduce crosstalk on high-speed channels. Contact feet on the board-side of a connector are flipped to increase the physical separation between contacts carrying transmit (TX) and contacts carrying receive (RX) signals. Meanwhile, for some embodiments the input receptacle side of the connectors are the same as that defined by standards such as SFF-8482, SFF-8630, SFF-8680 standards and the PCI-SIG, SFF-8639 Module Specification. This enables the connectors to work with existing devices employing these standards, such as NVMe drives. In one aspect, the connectors comprise modified versions of U.2 and U.3 connectors where selected board-side contacts (e.g., TX−, TX+, optional GND) and the mating contact pads used for SMT dual mount termination are staggered. In one aspect, the connector solutions are targeted for PCIe 5.0 and later NVMe implementations, noting the principles and techniques disclosed may apply to other high-speed channels.

### BACKGROUND INFORMATION

Connectors used in a high-speed transmission channel are identified as a major source of crosstalk. As the speed increases, electromagnetic coupling and crosstalk becomes more critical for IO (input-output) topologies. With new platforms, form factors (like DC-MHS) and complex systems, the impact of connectors on a high-speed topology has a big effect. Traditionally TX (transmit) pairs and RX (receive) pairs are separated in two different rows for high-speed connectors, with the U.2 and U.3 connectors being exceptions.

U.2, which is specified by SFF-8639, is a computer interface standard for connecting solid-state drives (SSDs) to a board in a computer system or platform, such as to a computer's system board. SFF-8639 covers the physical connector, electrical characteristics, and communication protocols. It was developed for the enterprise market and designed to be used with new Peripheral Component Interconnect Express (PCIe) drives along with SAS and SATA drives. It uses up to four PCI Express lanes and two SATA lanes.

U.3 has the same form physical factor as SFF-8636, but uses different signal/pin assignments and is specified in SFF-TA-1001. U.3 is named after its tri-mode capability under which a single PHY on a storage controller host may provide connectivity for SAS, SATA, and PCIe devices.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a diagram showing the U.2 pinout on the input side as defined by SFF-8639;

FIGS. 2a and 2b respectively show receptacle views of the U.2. connector, and views of the U.2 connector plug, as specified in SFF-8639;

FIG. 3 is a diagram illustrating groups of pin (contact) assignments for conventional U.2 and U.3 connectors;

FIG. 4 shows a plan view and 3D view of the bottom (board-side) of a conventional U.2/U.3 connector;

FIG. 5 shows the contact pad footprint specified for a U.2/U.3 connector for a SMT implementation referred to as a surface mount dual row board termination, as specified in SFF-8639;

FIG. 6 shows a plan view and a 3D view of a bottom (board-side) of a U.2 connector with flip staggered contacts under which the contacts for TX− and TX+ signals are flipped and staggered, according to one embodiment;

FIG. 7 shows the contact pad footprint for a modified surface mount dual row board termination configured to be used with the U.2. connector of FIG. 6, according to one embodiment;

FIG. 7a shows the contact pad footprint for a modified surface mount dual row board termination configured to be used with the U.2. connector having contacts for TX−, TX+ and GND signals flipped and staggered, according to one embodiment;

FIG. 8 shows a plan view and a 3D view of a bottom (board-side) of a U.3 connector with flip staggered contacts under which the contacts for TX−, TX+, and GND signals are flipped and staggered, according to one embodiment;

FIG. 9 shows the contact pad footprint for a modified surface mount dual row board termination configured to be used with the U.3 connector of FIG. 8, according to one embodiment;

FIG. 10 shows a plan view and a 3D view of a bottom (board-side) of a universal U.2+U.3 connector with flip staggered contacts under which the contacts for TX−, TX+, and GND signals are flipped and staggered, according to one embodiment;

FIG. 11 shows the contact pad footprint for a modified surface mount dual row board termination configured to be used with the U.2+U.3 connector of FIG. 10, according to one embodiment;

FIG. 12 shows an abstracted view of an example use case implemented with a PCB including an instance of the contact pad footprint shown in FIG. 7;

FIG. 13 is a diagram illustrating a pooled storage drawer, according to one embodiment;

FIG. 14 shows a first example of a backplane PCB implementing m instances of the contact pad footprint of FIG. 7 and a PCIe switch chip having m 4 lane PCIe interfaces;

FIG. 15a shows a second example of a backplane PCB implementing m instances of the contact pad footprint of FIG. 9 and a PCIe switch chip having m 4 lane PCIe interfaces;

FIG. 15b shows the backplane PCB of 15b with m U.3 connectors mounted to respective instances of the contact pad footprint of FIG. 9; and

FIG. 16 is a graph illustrating comparing crosstalk performance of a new flip stagger U.2 connector and a conventional U.2 connector.

### DETAILED DESCRIPTION

Embodiments of methods and apparatus for staggered flip pin SMT (surface mount technology) connector to reduce crosstalk on high-speed channels are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

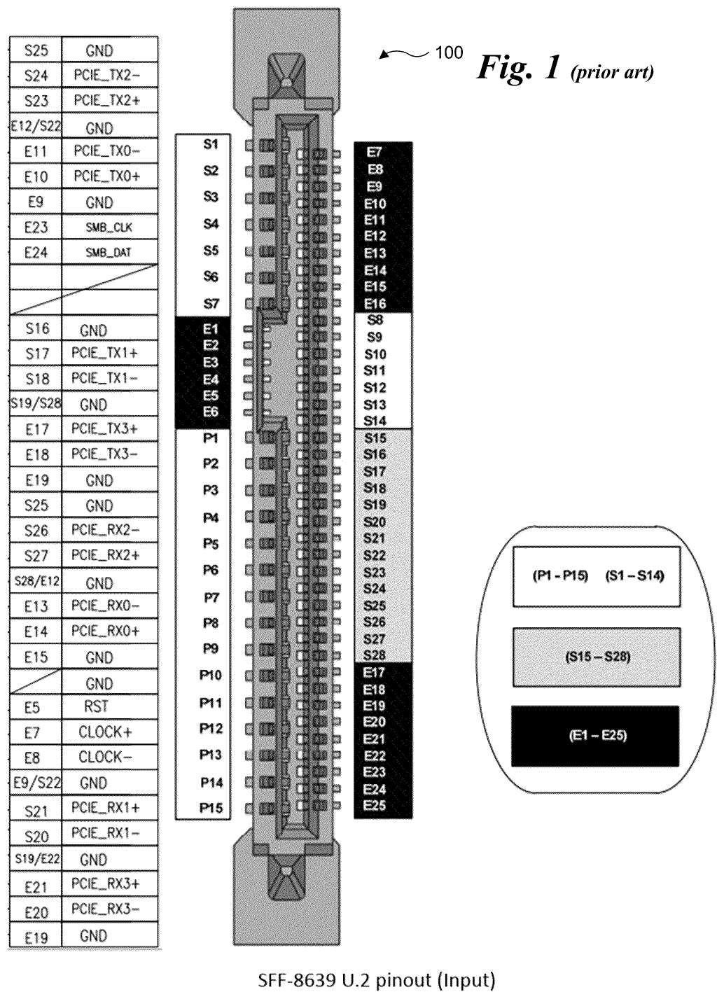

FIG. 1 shows a top view of a U.2 connector 100, along with its pinout (signal to pin/contact assignments) and contact numbering scheme, as defined in SFF-8639. As used herein and under conventional terminology used in the art, the terms “pin” and “contact” may be interchangeably used. The contact numbering scheme is an extension of the contact numbering schemes defined in SFF-8482 and SFF-8630. The contact numbering started with the contacts defined in SFF-8482 (P1-P15 and S1-S14). The numbering scheme was extended to cover the use case of a SAS MultiLink connector (S15-S28) as defined in SFF-8630. Additional contacts (E1-E25) were added to cover the use case of a 4-lane PCIe connector.

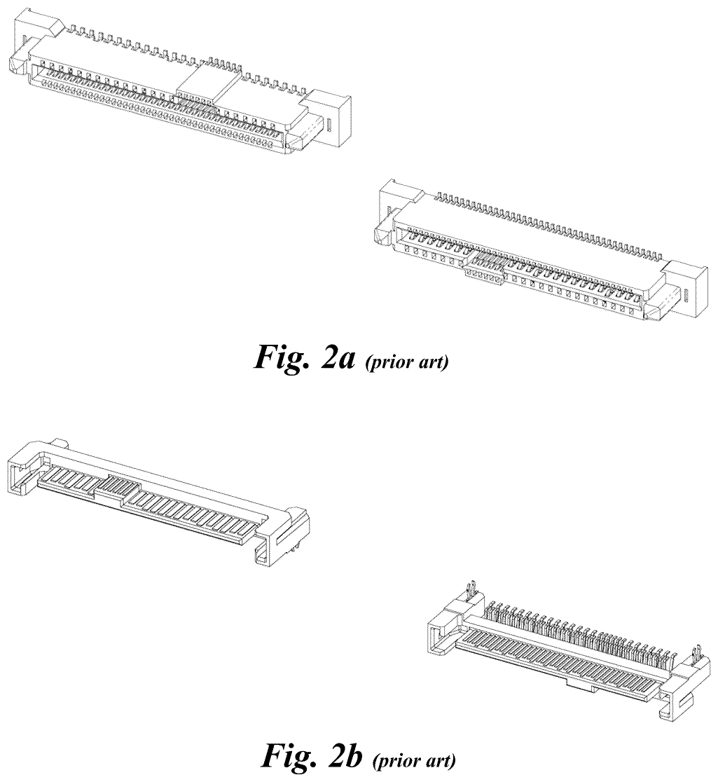

FIGS. 2a and 2b respectively show receptacle views of the U.2. connector, and views of the U.2 connector plug. This connector system is designed to allow devices that support single port SATA, dual port SATA Express, dual port SAS, MultiLink SAS, or up to four-port PCIe port plugs to mate to a common fixed receptacle that is mechanically compatible to the connector receptacles designed in accordance with SFF-8482 or SFF-8630. The interface supports all the contact sets defined by a dual port SAS implementation plus an additional 39 signals. The additional 39 signals may be used to support 4 lanes of PCIe plus 10 sideband signals. In a MultiLink SAS implementation 14 of the 39 signals are used to support the two additional SAS ports.

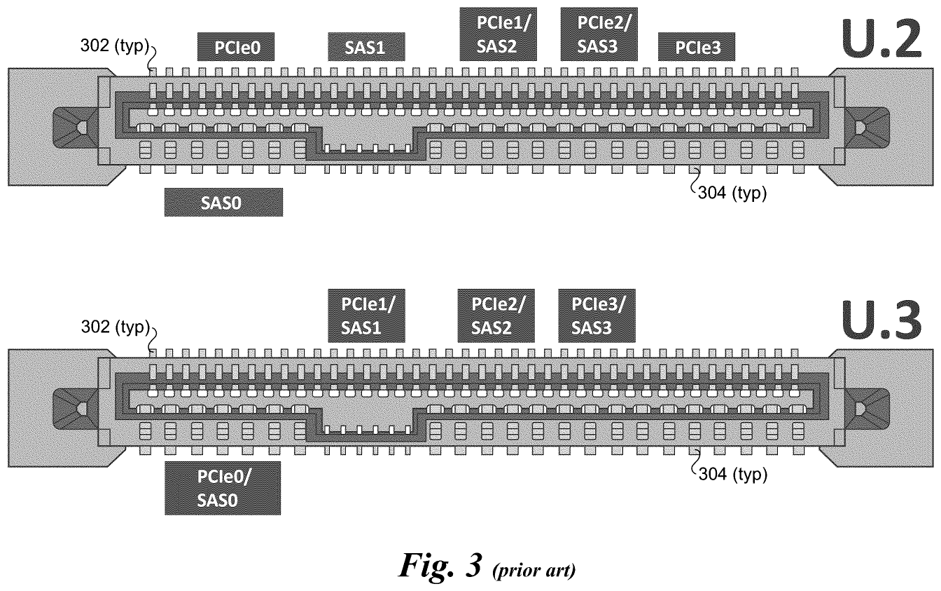

FIG. 3 shows groups of pin (contact) assignments for conventional U.2 and U.3 connectors. The SAS ports are labeled SAS0, SAS1, SAS2, and SAS3. The PCIe ports are labeled PCIe0, PCIe1, PCIe2, and PCIe3. As shown in FIG. 1 for a U.2 connector, in addition to the 5 pin/contacts for each labeled SAS or PCIe ports shown in FIG. 3, there are other pins/contacts used for ground (GND), Clock+, Clock−, reset (RST), SMB_CLK, and SMB_DAT.

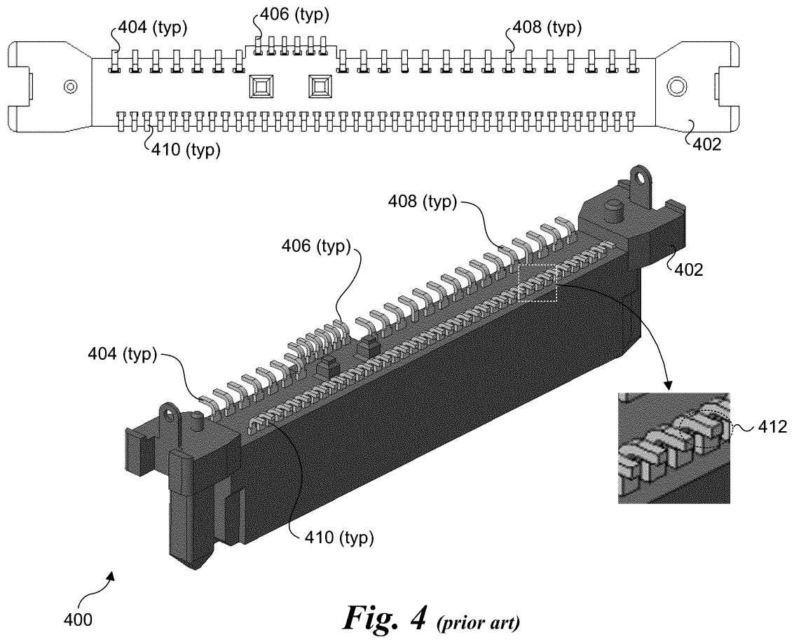

As mentioned above, the U.2 and U.3 connectors have the same physical interface (specified by SFF-8639). FIG. 4 shows a plan view and 3D view of the bottom (board-side) of a U.2/U.3 connector 400. The connector includes a connector body 402 and various sets of contacts, including a set of (7) contacts 404, a set of (6) contacts 406, a set of (15) contacts 408 and a set of (40) contacts 410. Contacts 404 and 408 have similar mechanical configurations.

Each of these contacts have an end portion comprising a “foot,” such as depicted by a foot 412 for contacts 410. The planar surface of the foot is what is soldered to a mating contact pad using SMT, such as but not limited to a solder reflow operation.

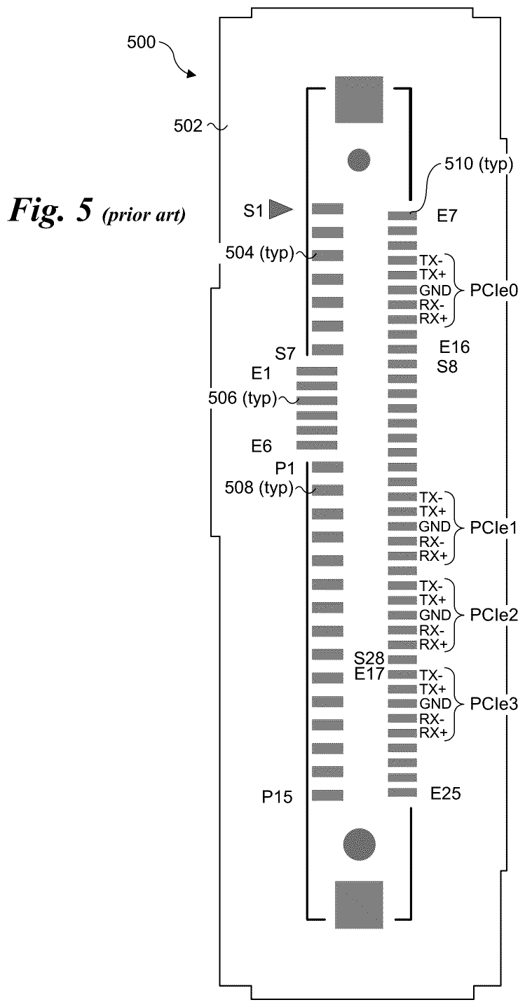

FIG. 5 shows the contact pad footprint 500 specified for a U.2/U.3 connector that is coupled to a printed circuit board (PCB) 502 for a SMT implementation referred to as a surface mount dual row board termination, as specified in SFF-8639. The contact pads include a set of (7) contact pads 504, a set of (6) contact pads 506, a set of (15) contact pads 508, and a set of (40) contact pads 510. When oriented vertically, the contact pads are grouped into two columns of contact pads, where contact pads 504, 506, and 508 are associated with a first column and contact pads 510 are associated with a second column. Under conventional terminology where the orientation of the connector (and contact pad footprint) is horizontal, the contact pad layout is grouped into two (dual) rows (thus the “dual row” SMT board termination terminology used in SFF-8639).

Contact pad footprint 500 is further annotated to show pin/contact numbers and RX, GND, and TX signals for each of PCIe ports PCIe0, PCle1, PCIe2, and PCIe3 corresponding to the footprint of a U.2 connector. A U.2 connector has an interleaved pin pattern where TX pins are placed in proximity to RX pins in the same row. More particular, the pin/contact sequence is TX−, T+, GND, RX−, and RX+. A given PCIe lane comprises a pair of differential TX signals (TX− and TX+) and a pair of differential RX signals (RX− and RX+)

The pinout (contact and contact pad) configuration for the conventional U.2 connector suffers from near end crosstalk (NEXT) coming from two neighboring pairs of TX and RX signals. Furthermore, NEXT is a bigger challenge, because of the strength of the coupling signal which is not as strongly attenuated from the transmitter placed only 6.5 dB (Insertion Loss of PCIe5 U.2 SSD) away. PCIe6 performance and solution space for U.2 and U.3 is questionable considering the NEXT disadvantage of the U.2 footprint and lower performance of U.2 connector at PCIe5 compared to EDSFF (Enterprise and Datacenter Standard Form Factor) connectors. It is important to mitigate near end crosstalk challenges in U.2 connectors to enable the U.2 form factor for PCIe6 applications.

A similar NEXT challenge applies to the PCIe ports PCIe1, PCIe2, and PCIe3 for the U.3 pinout. Since the spacing of the RX and TX differential signals is larger for port PCIe0, the level of NEXT is less than for PCIe ports PCIe1, PCIe2, and PCIe3.

In accordance with aspects of the embodiments described and illustrated herein, an innovative staggered pin flip SMT connector for high-speed channels is provided. The core of this innovation lies in alternately inverting or flipping the connector pins (all TXs or all RXs) in a staggered fashion, increasing the relative distance (spatial separation) between the pins such that neighboring TX-RX pairs distance/separation is increased. Intentional separation minimizes electromagnetic coupling (NEXT), improving signal integrity and overall channel performance, allowing for an increase in solution space and to enable the use of U.2 and U.2 connectors for higher data rates. Moreover, these solutions do not require additional equalization methods or active or passive elements in the transmission channel (although these may be optionally combined with the innovative connector solutions.

Another aspect of some embodiments is of the connector solutions is they are compatible with the same plug interfaces defined for SFF-8482, SFF-8630 and SFF-8680 standards; and the PCI-SIG, SFF-8639 Module Specification, the latter of which is used for PCIe implementations. This enables the innovative connectors to be used with existing NVMe drives that employ plug interfaces in accordance with the PCI-SIG, SFF-8639 Module Specification.

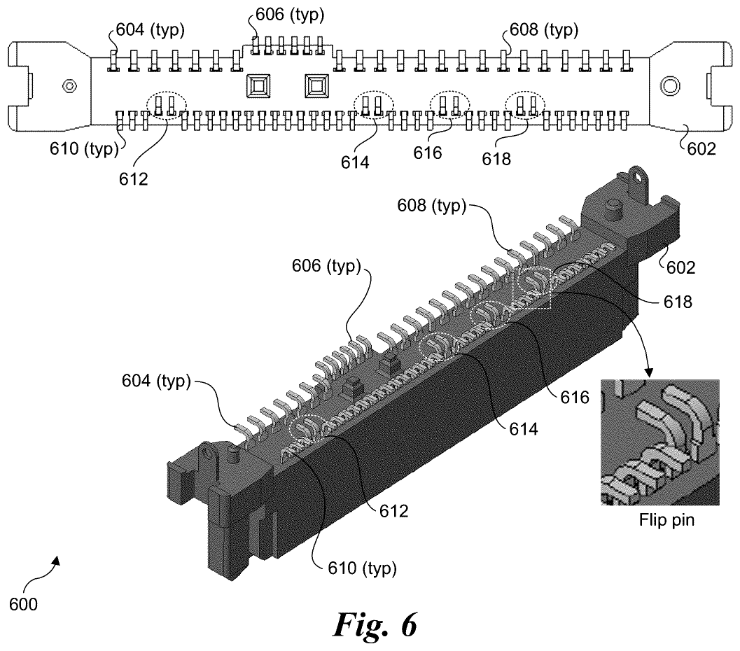

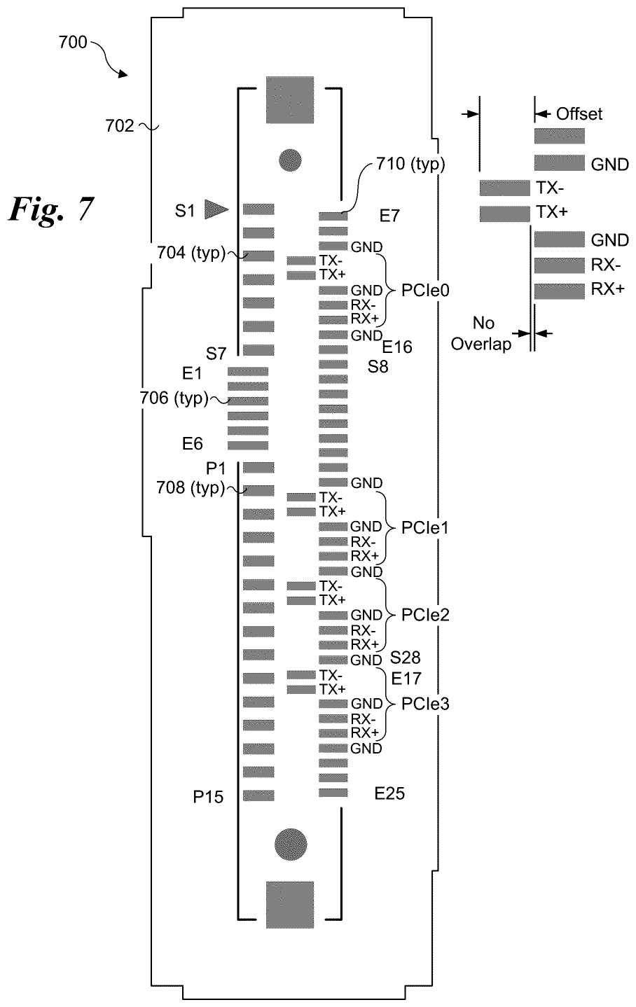

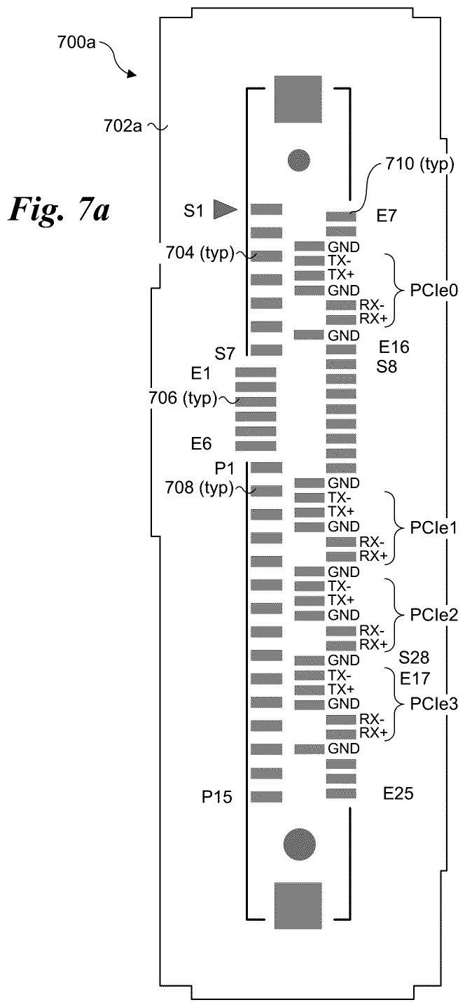

FIG. 6 shows a plan view and a 3D view of a bottom (board-side) U.2 connector 600 with flip staggered contacts, according to one embodiment. In this example, the U.2 connector is targeted for supporting a 4-lane PCIe interface, such as for but not limited to an NVMe drive using PCIe5, PCIe6 or a next generation of PCIe signaling. Connector 600 includes a connector body 602 and various sets of contacts, including a set of (7) contacts 604, a set of (6) contacts 606, a set of (15) contacts 608 and a set of (40) contacts 610. In this embodiment, contacts 604, 606, and 608 respectively have identical configurations to contacts 404, 406, and 408 in the conventional U.2/U.3 connector 400 of FIG. 4. However, in this first exemplary configuration the orientation of the feet of contacts 612, 614, 616 and 618 are flipped relative the feet of the other contacts 610. This is referred to as “flip stagger,” wherein the foot of a given flipped contact is oriented in a direction that is opposite the direction of the non-flipped contacts, with the result being the foot portion of the contacts that will be soldered to the contact pads are staggered, as shown in contact pad footprint 700 in FIG. 7. Under this first example, the feet of the contacts carrying the TX signals (TX− and TX+) are flipped for each of PCIe0, PCIe1, PCIe2 and PCIe3 interfaces.

In further detail, contact pad footprint 700 is a modified version of the contact pad footprint for a U.2/U.3 connector specified in SFF-8639 for a SMT implementation referred to as a surface mount dual row board termination. As before (for contact pad footprint 500 in FIG. 5) the contact pads formed on the top surface of a PCB 702. The contact pads include a set of (7) contact pads 704, a set of (6) contact pads 706, a set of (15) contact pads 708, and a set of (40) contact pads 710. The size, location, and pitch of contact pads 704, 706, and 708 are identical to the size and location of the contact pads in the first column/row specified by SFF-8639. Conversely, while the size and pitch of contact pads 710 are as defined in SFF-8639, the contact pads, contact pads used for the TX− and TX+ signals for each of the PCIe ports PCIe0, PCIe1, PCIe2 and PCIe3 are staggered relative to the other contact pads 710 in the second column/row.

Generally, as described and illustrated herein, staggered contact pads comprise contact pads used for carrying and assigned to TX (TX− and TX+) signals being offset from contact pads used for carrying and assigned to RX (RX− and RX+) signals. In the vertical orientation, the offset is in the horizontal direction (as shown in blowup FIG. 7) while when the connector is oriented horizontally the offset will be in the vertical direction. In the example shown in contact pad footprint 700 and other examples described and illustrated herein, the TX signal contacts/contact pads are offset. In some embodiments, only the TX signal contacts/contacts pads are offset relative to the other contacts/contact pads, while in other embodiments additional contacts/contact pads may be offset, such as for GND. While not separately shown, in other embodiments the RX signal contacts/contact pads are offset relative to the other contacts/contact pads.

As shown in FIG. 7, the TX− and TX+ contact pads are “fully” offset such that there is no overlap between the TX− and TX+ contact pads and the other contact pads. Depending on the signal crosstalk characteristics and application, a staggered flip pin solution may include more or less amount of offset, including cases where there may be some overlap between the contact pads for TX signals and RX signals.

FIG. 7a shows another embodiment of a contact pad footprint 700a comprising an alternative configuration under which GND contact pads on PCB 702a are also staggered with the TX− and TX+ pads for each of PCIe ports PCIe0, PCIe1, PCIe2, and PCIe3. In this example, both the GND contact pads above each TX− contact pad and below each TX+ contact pad is offset along with the TX− and TX+ contact pads. Moreover, both the GND contact pad above each RX− contact pad and below each RX+ contact pad is offset relative to those RX contact pads.

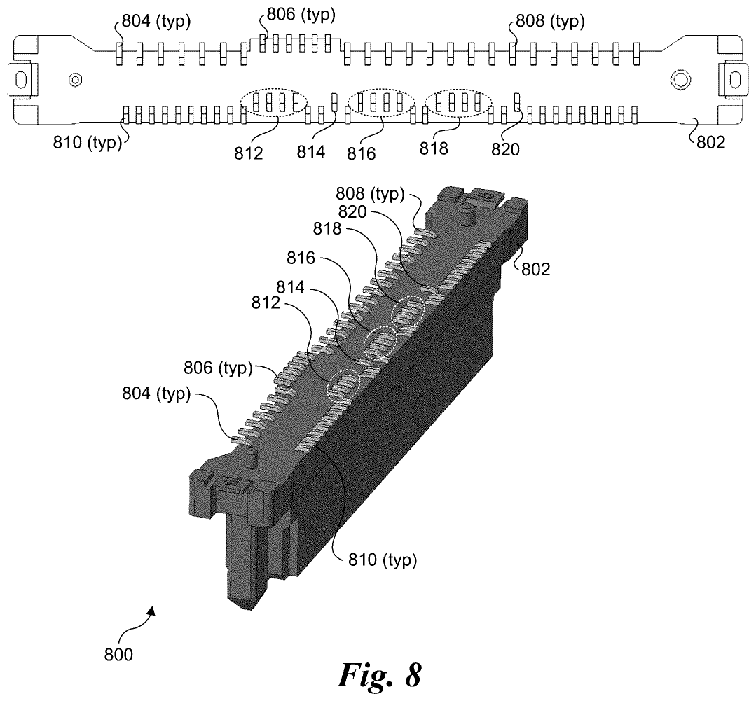

FIG. 8 shows a bottom view and a 3D view of a U.3 connector 800 with flip staggered contacts, according to one embodiment. In this example, the U.3 connector is targeted for supporting a 4-lane PCIe interface, such as for but not limited to an NVMe drive using PCIe5, PCIe6 or a next generation of PCIe signaling. Connector 800 includes a connector body 802 and various sets of contacts, including a set of (7) contacts 804, a set of (6) contacts 806, a set of (15) contacts 808 and a set of (40) contacts 810. In this embodiment, contacts 804, 806, and 808 respectively have identical configurations to contacts 404, 406, and 408 in the conventional U.2/U.3 connector 400 of FIG. 4. In the U.3 connector 800 the orientation of the feet of (4) contacts 812, contact 814, (4) contacts 816, (4) contacts 818 and contact 820 are flipped relative the feet of the other contacts 810.

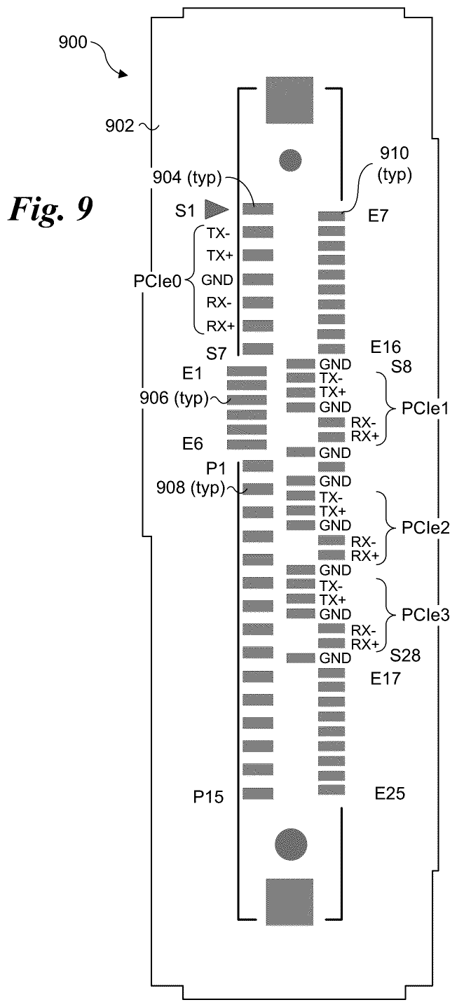

FIG. 9 shows an embodiment of a U.3 contact pad footprint 900 configured to be used for U.3 connector 800, where the contact pads are formed on the top surface of a PCB 902. The contact pads include a set of (7) contact pads 904, a set of (6) contact pads 906, a set of (15) contact pads 908, and a set of (40) contact pads 910. The size, location, and pitch of contact pads 904, 906, and 908 are identical to the size and location of the contact pads in the first column/row specified by SFF-8639. Conversely, while the size and pitch of contact pads 910 are as defined in SFF-8639, the contact pads, contact pads used for the TX− and TX+ signals and the adjacent GND contact pads for each of the PCIe ports PCIe1, PCIe2 and PCIe3 are staggered relative to the other contact pads 710 in the second column/row. In addition, the GND contact pads above each RX− signal contact pad and below each RX+ signal contact pad is also staggered. As further shown, the contacts used for the TX−, TX+, GND, RX−, and RX+ signals for PCIe0 are the same as for a conventional U.3 connector.

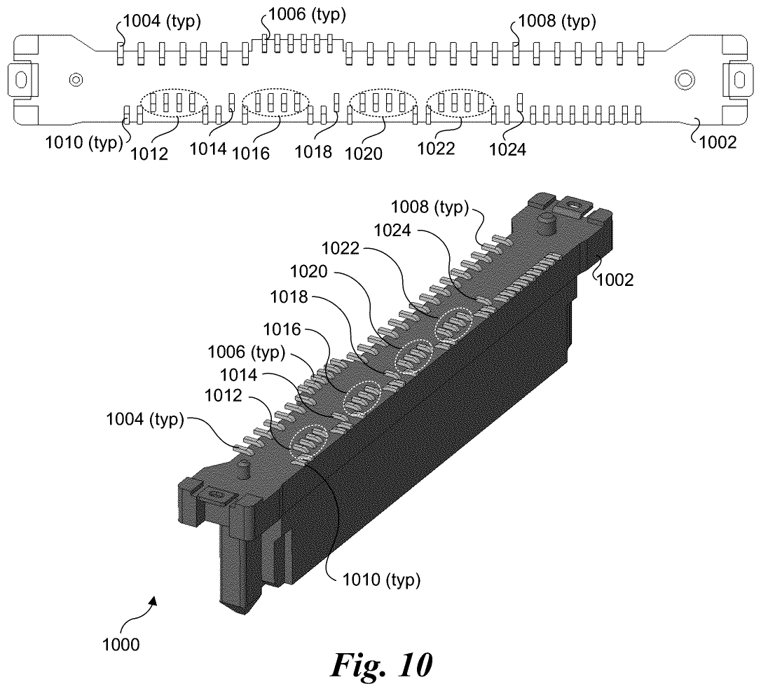

FIG. 10 shows a bottom view and a 3D view of a universal U.2+U.3 connector 1000 with flip staggered contacts, according to one embodiment. In this example, connector 1000 is configured to support a 4-lane PCIe interface using either U.2 or U.3 pin/contact to signal assignments. As above, the 4-lane PCIe interface may be used for, but is not limited to an NVMe drive using PCIe5, PCIe6 or a next generation of PCIe signaling. Connector 1000 includes a connector body 1002 and various sets of contacts, including a set of (7) contacts 1004, a set of (6) contacts 1006, a set of (15) contacts 1008 and a set of (40) contacts 1010. In this embodiment, contacts 1004, 1006, and 1008 respectively have identical configurations to contacts 404, 406, and 408 in the conventional U.2/U.3 connector 400 of FIG. 4. In connector 1000 the orientation of the feet of (4) contacts 1012, contact 1014, (4) contacts 1016, contact 1018, (4) contacts 1020, (4) contacts 1022, and contact 1024 are flipped relative the feet of the other contacts 1010.

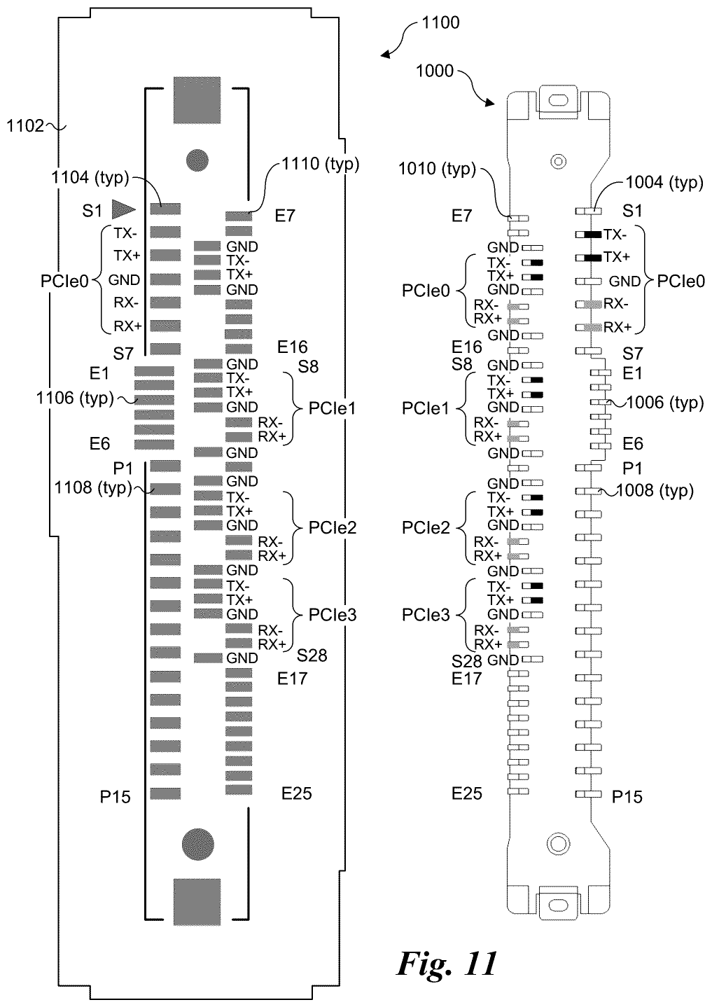

FIG. 11 shows an embodiment of a universal U.2+U.3 contact pad footprint 1100 configured to be used for U.2+U.3 connector 1000, where the contact pads are formed on the top surface of a PCB 1102. FIG. 11 also shows the pinout for the underside of U.2+U.3 connector 1000, which would be mounted to the contact pads using an SMT process. The contact pads include a set of (7) contact pads 1104, a set of (6) contact pads 1106, a set of (15) contact pads 1108, and a set of (40) contact pads 1110. The size, location, and pitch of contact pads 1104, 1106, and 1108 are identical to the size and location of the contact pads in the first column/row specified by SFF-8639. Conversely, while the size and pitch of contact pads 1110 are as defined in SFF-8639, the contact pads, contact pads used for the TX− and TX+ signals and the adjacent GND contact pads for each of the PCIe ports PCIe1, PCIe2 and PCIe3 are staggered relative to the other contact pads 1110 in the second column/row. In addition, the GND contact pads above each RX− signal contact pad and below each RX+ signal contact pad is also staggered. As further shown, the contacts used for the TX−, TX+, GND, RX−, and RX+ signals for PCle0 are the same as for a conventional U.2 connector and for a conventional U.3 connector.

The use of universal U.2+U.3 connector 1000 and universal U.2+U.3 contact pad footprint 1100, in combination with wiring (wire traces and vias) in a PCB enable the same connector to support a 4-lane PCIe interface using either U.2 or U.3 pin/contact to signal assignments. In some implementations, circuitry on the PCB, such as multiplexer (MUX) and control circuitry may be used to select which PCIe0 signals are coupled to the PCIe lane 0 interface on the IC chip having a 4-lane PCIe interface.

### EXEMPLARY USE CASES

Generally, the embodiments of the connector solutions disclosed herein may be used anywhere existing conventional U.2 and U.3 connectors are used. This includes, but is not limited to, backplane implementations, such in pooled storage apparatus and data center or edge servers. Stand-alone computer systems and servers may also implement the novel U.2, U.3, and universal U.2+U.3 connectors.

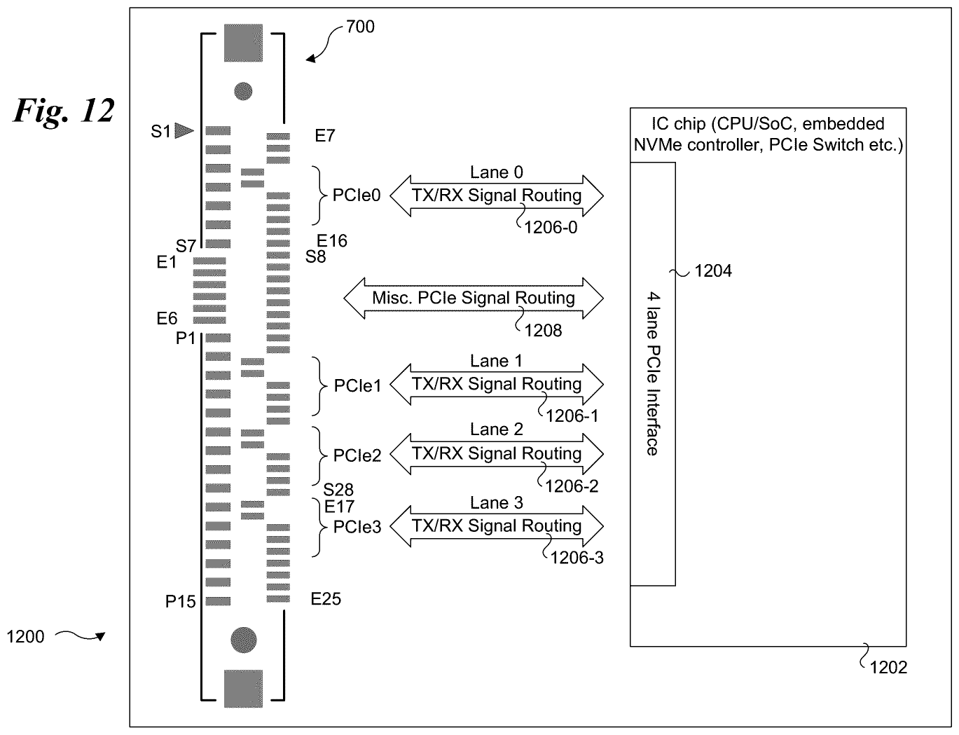

FIG. 12 shows an abstracted view of an example use case implemented with a PCB 1200. Connector pads corresponding to one of the contact pad footprints disclosed herein, such as contact pad footprint 700 show here, are formed on the top surface/layer of PCB 1200. An integrated circuit (IC) chip or package, such as IC chip 1202, is mounted to PCB via a set of pads (not shown) that are (generally) disposed under the IC chip when it is mounted to the PCB. For example, IC chip may be installed in a Ball Grid Array (BGA) interposer that sits between the IC chip and the PCB or the IC chip or package may include an integrated BGA. The BGA comprises a 2D array of solder balls formed over pads on the underside of the IC chip/package or BGA interposer. A mating 2D array of pads are formed on the top surface/layer of PCB 1200, and the BGA is mounted to the PCB 1200 using SMT, such as using a solder reflow operation or the like.

As is known, a PCB such as PCB 1200 will include a stack of layers with some layers having routed electrical traces (aka “wiring”) interposed between other layers that may be used for providing power and or ground to selected pads used for IC chips/packages and SMT connectors on the PCB. Vias or the like are used to provide electrical pathways between layers. This structure/circuitry facilitates connectivity between selected pad for contact pad footprint 700 and associated pads used for the IC chips/packages. For example, in this example IC chip 1202 comprises a CPU (central processing unit) or SoC (System on a Chip), and embedded NVMe controller, PCIe switch chip, etc. IC chip 1202 includes one or more PCIe interfaces, such as the 4 lane PCIe interface 1204 shown in FIG. 12. Wiring and vias are formed in PCB 1200 to connect the TX and RX signals for applicable contact pads for each of the four PCIe ports PCIe0, PCIe1, PCIe2, and PCIe3 for contact pad footprint 700 and associated pads to which mating pads on IC chip 1202 are coupled via the BGA/SMT mounting of IC chip 1202. These TX and RX signals are depicted as TX/RX routing signals 1206-0, 1206-1, 1206-2, and 1206-3 for respective PCIe lanes 0, 1, 2, and 3. In addition, signal routing 1208 comprises applicable wiring and vias is used to couple miscellaneous PCIe signals between contact pads for contact pad footprint 700 and applicable contact pads for IC chip 1202.

One example use case is for a pooled storage apparatus such as a pooled storage “drawer”, chassis, sled, etc. Pooled storage apparatus may comprise multiple mass storage devices, such as NVMe drives, and are sometimes referred to as “Just a Bunch Of Disks” (JBODs).

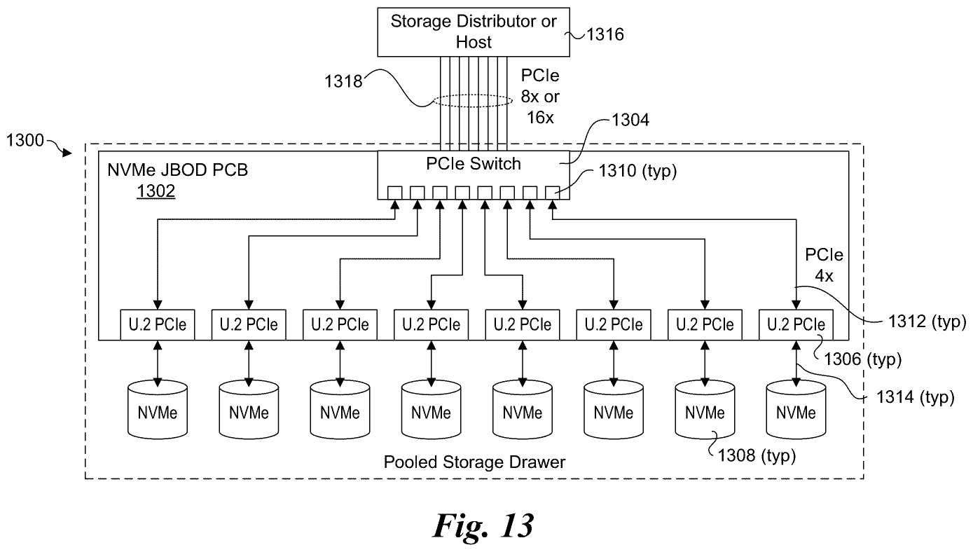

An example of a pooled storage drawer 1300 is shown in FIG. 13. Pooled storage drawer 1300 includes an NVMe JBOD PCB 1302 to which a PCIe switch 1304 and eight U.2 PCIe connectors are mounted using SMT. U.2 PCIe connectors may include U.2 connector 600 employing either contact pad footprint 700 or 700a. As an alternative, U.3 connector 800 or universal U.2+U.3 connector 1000 may be used. A respective NVMe drive 1308 is coupled to each U.2. PCIe connector 1306. PCIe switch 1304 includes eight 4 lane PCIe ports 1310, with respective instances of wiring 1312 for facilitating a 4 lane PCIe link (commonly referred to as PCIe 4x) coupling each 4 lane PCIe port 1310 to a respective U.2 PCIe connector 1306. PCIe switch 1304 also includes one or more additional input-output (IO) interfaces to couple to one or more storage distributor or host 1316. In the illustrated embodiment, the connection between PCIe switch 1304 and storage distributor or host 1316 is either a PCIe 8x or 16x link 1318.

A common configuration for a pooled storage apparatus or the link is to have multiple U.2 or U.3 connectors mounted to a backplane (PCB) that is vertically disposed and installed in the back of the apparatus housing, such as a drawer, chassis, sled, etc. When drawer, chassis, sled, etc. is installed in a rack, the NVMe drives are usually oriented vertically. Under other pooled storage apparatus, the NVMe drives may be coupled to a base plane or system board or the like that is oriented horizontally rather than vertically. The backplane, base plane or system board may have one or more IC chips or packages, such as the PCIe switch chips illustrated in the Figures below.

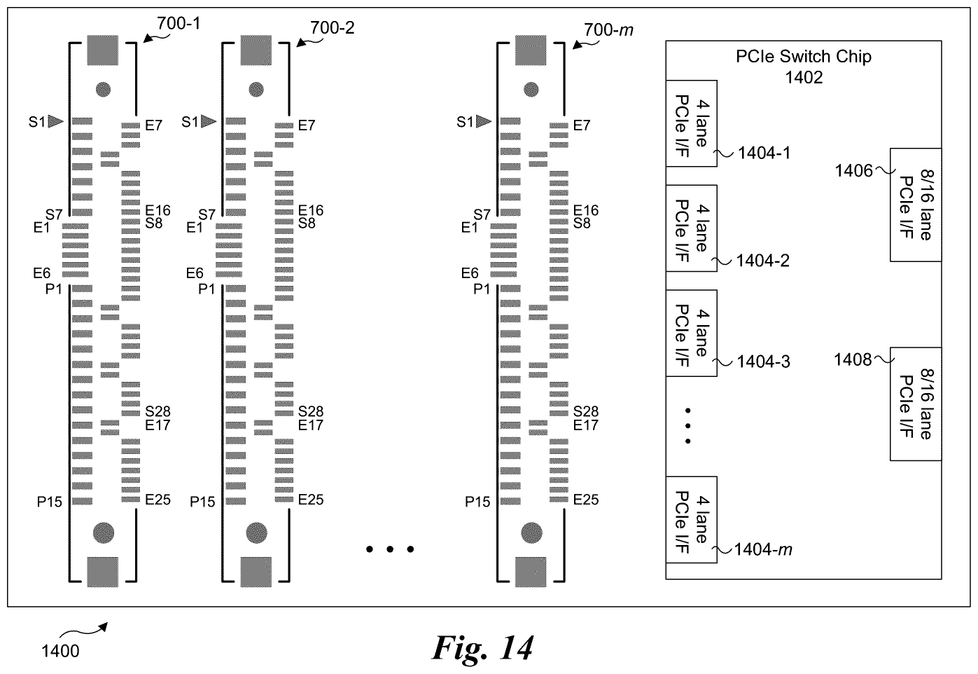

FIG. 14 show a backplane 1400 in which m instances of contact pad footprint 700-1, 700-2, . . . 700-m are patterned on the backplane PCB, where m is an integer, such as 8, 10, 12, 14, 16, etc. Backplane 1400 also includes a PCIe switch chip 1402 having m 4 lane PCIe interfaces 1404-1, 1404-2, 1404-3 . . . 1404-m. PCIe switch chip 1402 also includes a pair of 8 or 16 lane PCIe interfaces 1406 and 1408. The PCB for backplane 1400 would further include wiring and vias coupling the pads for TX and RX signals for each of PCIe ports PCIe0, PCIe1, PCIe2, and PCIe3 for each of contact pad footprint 700-1, 700-2, . . . 700-m to appropriate BGA pads underneath PCIe switch chip 1402 (both wiring and BGA pads not shown).

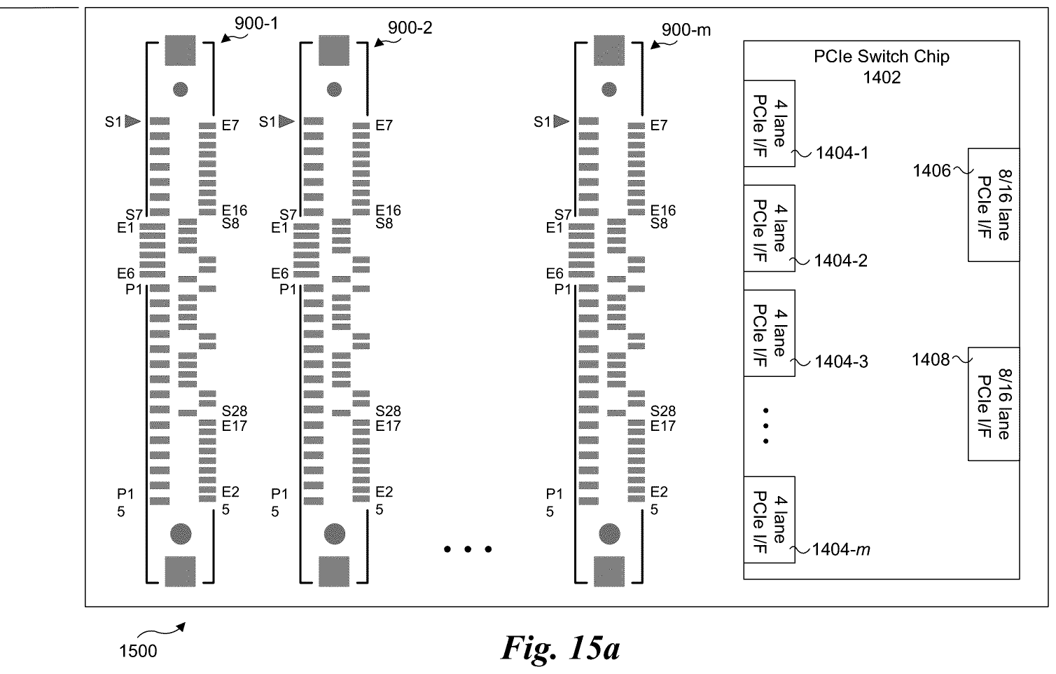

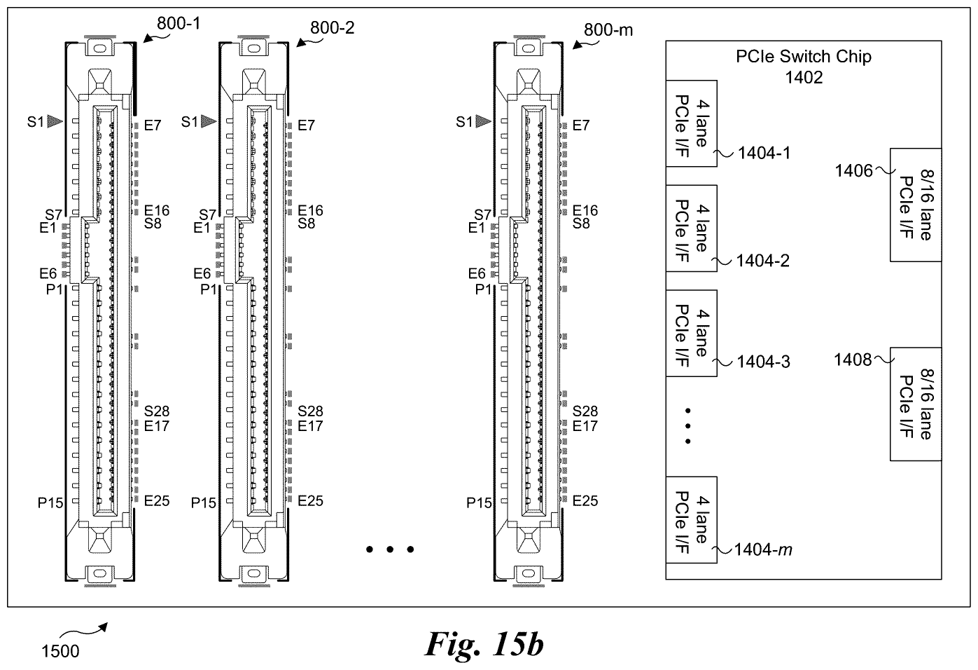

FIG. 15a shows a backplane 1500 that is like backplane 1400, except in this case there are m instances of contact pad footprints 900-1, 900-2 . . . 900-m that are suitable for use with U.3 connector 800. FIG. 15b shows backplane 1500 with the m instances of U.3 connectors 800-1, 800-2 . . . 800-m having contact feet mounted to the contact pads for respective contact pad footprints 900-1, 900-2 . . . 900-m using SMT.

In one embodiment, PCIe switch chip is a Microchip® Switchtec™ PCIe switch chip that supports PCIe Gen 5 (PCIe 5.0 specification). For example, this may include PFX Gen 5 Fanout PCIe Switch Family models PCIe® Switch Family models PM50100, PM50084, PM50068, PM50052, PM50036, and PM50028.

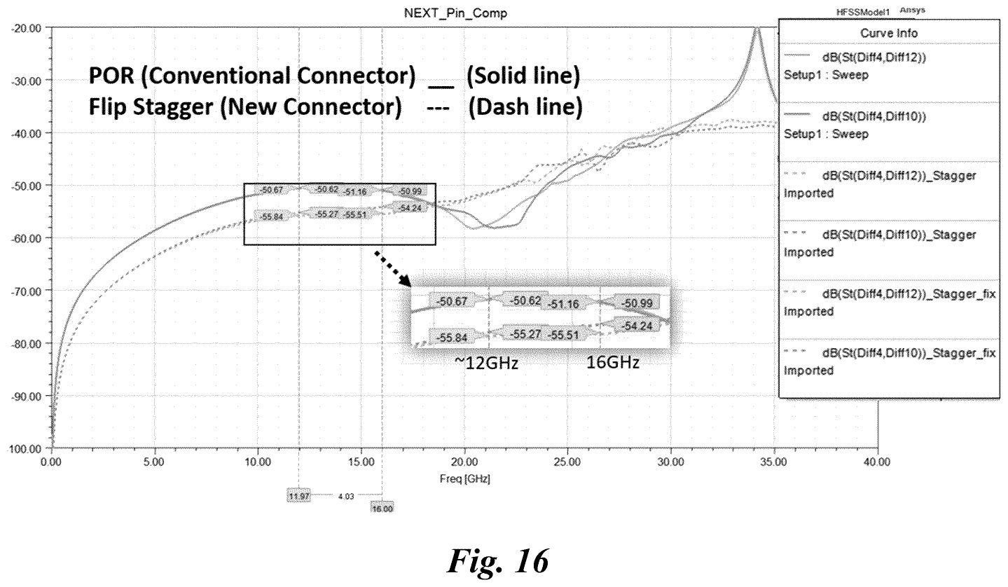

The novel crosstalk-reducing staggered pin SMT connector introduces a significant improvement by increasing pad spacing compared to conventional assemblies. This intentional increase in spacing has substantial implications on the overall performance of the connector, especially in reducing crosstalk levels. FIG. 16 shows the near-end crosstalk results of the novel staggered pin SMT U.2 connector, versus the conventional U.2 connector. Note that the extended separation minimizes crosstalk between adjacent pads, contributing to a marked improvement in signal integrity within the PCIe 5.0 channel. In this example, there is approximately 4.5 dB delta improvement at 16 GHz, which is the operating frequency of a PCIe channel. Similar benefit is realized for PCIe 6.0 channels.

Performance improvements for the Eye Height and Eye Width under one embodiment of a U.2 solution are shown in TABLE 1. Based on these results, it is evident that this crosstalk reduction directly translates into an improvement in total margin, indicating the possibility of a greater maximum routing length that the channel can support without compromising performance.

TABLE 1

| | U.2 | TX pairs | |
|---|---|---|---|
| Nominal | Minimal | New connector, | Conventional SFF |
| Channel Sims | Spec | Flip-stagger | PCIe Conn |
| Eye Height (V) | 1.67E−02 | 1.55E−02 | 1.52E−02 |
| Eye Width (UI) | 2.72E−01 | 2.64E−01 | 2.58E−01 |

The additional margins achieved by the disclosed connectors can expand the solution space for high-speed channels, representing an important option to improve performance or cost reduction. This improvement underlines the effectiveness of an innovative connector, which reduces signal degradation and therefore improves signal integrity margins on high-speed channels.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A connector, comprising:
a receptacle side, having a plurality of contacts having a first end portion configured to mate with respective contacts of a plug connector, the plurality of contacts including contacts in first and second rows; and
a board-side opposite the receptacle side, the board-side including second end portions of the plurality of contacts comprising feet configured to be soldered to respective contact pads on a printed circuit board or substrate,
wherein the contact feet are configured to support a dual row surface mount board termination, and
wherein, for at least one row of the dual row, the contact feet are configured in a staggered pattern under which contact feet that are used for Receive (RX) signals are disposed in a first direction and contact feet that are used for Transmit (TX) signals are disposed in a second direction opposite of the first direction.

2. The connector of claim 1, wherein the connector is configured to couple signals including Peripheral Component Interconnect Express (PCIe) RX and TX signals for multiple PCIe lanes, and the PCIe signals have a frequency of at least 16 GHz.

3. The connector of claim 2, wherein the plug connector comprises a four-port PCIe plug and the connector receptacle is designed in accordance with at least one of:
the SFF-8482, SFF-8630 or SFF-8680 standards; and
the PCI-SIG, SFF-8639 Module Specification.

4. The connector of claim 2, wherein the connector is configured to support PCIe RX and TX signals assigned to connector contacts in accordance with, one at a time, a U.2 and a U.3 signal to contact assignment, and wherein:
under the U.2 signal to contact assignments the RX and TX signals for PCIe0, PCIe1, PCIe2, and PCIe3 are staggered; and
under the U.2 signal to contact assignments the RX and TX signals for PCIe1, PCIe2, and PCIe3 are staggered.

5. The connector of claim 1, wherein the connector comprises a U.2 connector.

6. The connector of claim 1, wherein the connector comprises a U.3 connector.

7. The connector of claim 1, wherein on the board-side sets of contacts among the plurality of contacts have a pattern for each of a plurality of PCIe ports comprising, in sequence, a Tx− signal, a Tx+ signal, a ground signal, an Rx− signal, and an Rx+ signal.

8. The connector of claim 1, wherein only contacts used for the Tx signals are disposed in the second direction.

9. The connector of claim 1, wherein the connector includes a plurality of ground (GND) contacts, and wherein the contacts used for the Tx signals and a portion of the plurality of GND contacts are disposed in the second direction.

10. The connector of claim 1, wherein when the connector is configured vertically there is a horizontal gap between the contact pads on the PCB or substrate for the Tx signals and the contact pads on the PCB or substrate for the Rx signals.

11. An apparatus comprising a printed circuit board (PCB) or substrate having a plurality of contact pads formed on a top surface thereof, the plurality of contact pads arranged to support a dual row surface mount board termination for a connector having a board-side including a plurality of contacts having feet configured to be soldered to respective contact pads,
wherein contacts among the plurality of contacts are used for respective signals including Receive (Rx) signals, Transmit (Tx) signals, ground (GND) signals, and miscellaneous signals, and
wherein, for at least one row of the dual row surface mount board termination, contact pads are arranged in a staggered pattern under which contact pads used for Rx signals are offset from contact pads used for Tx signals.

12. The apparatus of claim 11, wherein at least a portion of the contact pads used for GND signals are staggered.

13. The apparatus of claim 11, wherein multiple sets of contact pads have a pattern for each of a plurality of Peripheral Component Interconnect Express (PCIe) ports comprising, in sequence, a Tx− signal, a Tx+ signal, a ground (GND) signal, an Rx− signal, and an Rx+ signal.

14. The apparatus of claim 13, further comprising:
an integrated circuit comprising a chip having a plurality of contacts for a multi-lane PCIe interface and mounted to the PCB or substrate via a set of chip contact pads; and
wiring in the PCB or substrate coupling Tx−, Tx+, Rx−, and Rx+ signals for the multiple PCIe ports via respective contact pads for those signals to corresponding pads among the set of chip contact pads.

15. An apparatus, comprising:
a printed circuit board (PCB) or substrate on which an integrated circuit (IC) device is mounted to a first plurality of contact pads formed on a surface of the PCB or substrate, the PCB including a second plurality of contact pads and wiring coupling at least a portion of contact pads in the first plurality of contact pads to at least a portion of contact pads in the second plurality of contact pads;
a connector, including,
a receptacle side, having a plurality of contacts having first end portions configured to mate with respective contacts of a plug connector, the plurality of contacts including contacts in first and second rows; and
a board-side including second end portions of the plurality of contacts comprising feet configured to be soldered to respective contact pads among the second plurality of contact pads,
wherein the contact feet are configured to support a dual row surface mount board termination, and
wherein, for at least one row of the dual row, the contact feet are configured in a staggered pattern under which contact feet that are used for Receive (RX) signals are disposed in a first direction and contact feet that are used for Transmit (TX) signals are disposed in a second direction opposite of the first direction.

16. The apparatus of claim 15, wherein the receptacle side of the connector is designed in accordance with at least one of:
the SFF-8482, SFF-8630 or SFF-8680 standards; and
the PCI-SIG, SFF-8639 Module Specification.

17. The apparatus of claim 15, wherein the IC chip includes a Peripheral Component Interconnect Express (PCIe) interface having four lanes, and the connector implements signaling for four PCIe ports according to U.2 or U.3 specification.

18. The apparatus of claim 15, wherein the connect comprises a first connector, further comprising:
multiple instances of the first connector, each instance of the first connector having contact feet soldered to a respective instance of the second plurality of contact pads, each instance of the first connector implementing signaling for a respective set of four PCIe ports according to U.2 or U.3 specification,
wherein the IC chip comprises multiple Peripheral Component Interconnect Express (PCIe) interfaces having four lanes each, and wherein the PCB includes further wiring connecting each respective set of four PCIe ports on a respective instance of the first connector to sets of contact pads among the first plurality of contact pads to which a respective PCIe interface in the IC chip is coupled.

19. The apparatus of claim 18, further comprising at least two NVMe (Non-volatile Memory Express) Drives, cach having a plug connector inserted into the receptacle side of a respective instance of the first connector.

20. The apparatus of claim 19, wherein the IC chip comprises a PCIe switch chip, and wherein the apparatus comprises a pooled NVMe storage apparatus.
